(19) United States
(12) Patent Application Publication
(10) Pub. No.: US 2023/0146811 A1
(43) Pub. Date: May 11, 2023

(54) LASER PROCESSING DEVICE AND INSPECTION METHOD

(71) Applicant: HAMAMATSU PHOTONICS K.K., Hamamatsu-shi, Shizuoka (JP)

(72) Inventors: Yuta KONDOH, Hamamatsu-shi, Shizuoka (JP); Takafumi OGIWARA, Hamamatsu-shi, Shizuoka (JP)

(73) Assignee: HAMAMATSU PHOTONICS K.K., Hamamatsu-shi, Shizuoka (JP)

(21) Appl. No.: 17/914,863

(22) PCT Filed: Mar. 4, 2021
(86) PCT No.: PCT/JP2021/008451

§ 371 Date: Sep. 27, 2022

(30) Foreign Application Priority Data
Apr. 2, 2020 (JP) 2020-066502

(51) Int. Cl. B23K 26/066; B23K 26/53; B23K 26/073

(52) U.S. Cl. CPC B23K 26/066; B23K 26/53; B23K 26/073

(57) ABSTRACT

A laser processing device includes: a stage that supports a wafer having a front surface, on which a plurality of functional elements are formed and a street region extends so as to pass between adjacent functional elements, and a back surface on a side opposite to the front surface; a light source that emits laser light to the wafer from the front surface side to form one or more modified regions inside the wafer; a spatial light modulator as a beam width adjusting unit; and a control unit that controls the spatial light modulator so that the beam width of the laser light is adjusted to be equal to or less than the width of the street region and a target beam width according to surface information including the position and height of a structure forming a functional element adjacent to the street region.

### TECHNICAL FIELD

One aspect of the present invention relates to a laser processing device and an inspection method.

### BACKGROUND ART

In order to cut a wafer including a semiconductor substrate and a functional element layer formed on one surface of the semiconductor substrate along each of a plurality of lines, a laser processing device that form a plurality of rows of modified regions inside the semiconductor substrate along each of the plurality of lines by emitting laser light to the wafer from the other surface side of the semiconductor substrate is known. A laser processing device described in Patent Literature 1 includes an infrared camera, so that it is possible to observe a modified region formed inside a semiconductor substrate, processing damage formed on a functional element layer, and the like from the back surface side of the semiconductor substrate.

### CITATION LIST

### Patent Literature

Patent Literature 1: Japanese Unexamined Patent Publication No. 2017-64746

### SUMMARY OF INVENTION

### Technical Problem

The laser processing device described above may form a modified region inside the semiconductor substrate by emitting laser light to the wafer from the surface side of the wafer on which the functional element layer is formed. When emitting the laser light from the surface side on which the functional element layer is formed, it is necessary to confine the laser light within a street, which is a region between adjacent functional elements, so that the laser light is not emitted to the functional elements. Conventionally, by controlling the width of the laser light with a slit or the like, the control of confining the laser light within the street is performed.

Here, a structure that forms the functional element may have a predetermined thickness (height). For this reason, even if the laser light can be confined within the street, the laser light may be blocked by a part of the structure with a height and accordingly, desired laser emission may not be possible.

One aspect of the present invention has been made in view of the above circumstances, and an object thereof is to perform desired laser emission by suppressing the blocking of laser light by a structure, such as a circuit.

### Solution to Problem

A laser processing device according to an aspect of the present invention includes: a stage that supports a wafer having a first surface, on which a plurality of elements are formed and a street extends so as to pass between adjacent elements, and a second surface on a side opposite to the first surface; an emission unit that emits laser light to the wafer from the first surface side to form one or more modified regions inside the wafer; a beam width adjusting unit that adjusts a beam width of the laser light; and a control unit that controls the beam width adjusting unit so that the beam width of the laser light is adjusted to be equal to or less than a width of the street and a target beam width according to surface information including a position and a height of a structure forming an element adjacent to the street.

In the laser processing device according to an aspect of the present invention, in a configuration in which the laser light is emitted to the wafer from the first surface side on which a plurality of elements are formed, the beam width of the laser light is adjusted to be equal to or less than the width of the street on the first surface and the target beam width according to the position and height of the structure forming the element. In this manner, since the beam width of the laser light is adjusted to be equal to or less than the width of the street and the target beam width considering the position and height of the structure forming the element, it is possible to adjust the beam width of the laser light so that not only is the laser light confined within the width of the street, but also the laser light is not blocked by the structure. Therefore, it is possible to perform desired laser emission (emission of laser that is confined within the street width and is not blocked by the structure) by suppressing the blocking of the laser light by the structure such as a circuit. That is, according to the laser processing device according to an aspect of the present invention, it is possible to suppress a reduction in the output of the laser light inside the wafer due to the blocking of the laser light by the structure. In addition, when the laser light is emitted to the structure such as a circuit, it is conceivable that an undesirable beam enters the inside of the wafer due to interference to degrade the processing quality. In this respect, by suppressing the blocking of the laser light by the structure (emission of the laser light to the structure) as described above, it is possible to prevent such degradation of the processing quality. In addition, depending on a structure, it is conceivable that the structure is melted by the emission of the laser light. In this respect as well, by suppressing the blocking of the laser light by the structure (emission of the laser light to the structure) as described above, it is possible to avoid the influence of the laser light on the structure (for example, melting of the structure).

The beam width adjusting unit may have a slit portion for adjusting the beam width by blocking a part of the laser light, and the control unit may derive a slit width relevant to a transmission region of the laser light in the slit portion based on the surface information and set the slit width in the slit portion. According to such a configuration, it is possible to adjust the beam width easily and reliably.

When the derived slit width is smaller than a limit value that enables formation of the modified region, the control unit may output information indicating that processing is not possible to an outside. Therefore, since a situation is avoided in which processing is performed despite being in a non-processable state in which a modified region cannot be formed (useless processing is performed), it is possible to perform efficient processing.

When the derived slit width is a slit width that increases a length of a crack extending from the modified region, the control unit may output information for prompting a change in processing conditions to an outside. Therefore, since it is possible to prompt a change in the processing conditions when the appropriate processing cannot be performed, it is possible to perform smooth processing.

The control unit may derive the slit width by further considering a processing depth of the laser light in the wafer. Even if the surface information is the same, the appropriate slit width differs depending on the processing depth. In this respect, by deriving the slit width in consideration of the processing depth, it is possible to derive a more appropriate slit width. Therefore, it is possible to appropriately suppress the blocking of the laser light by the structure.

When a plurality of modified regions are formed at different depths inside the wafer by emitting the laser light to an inside of the wafer, the control unit may derive the slit width for each combination of the surface information and the processing depth of the laser light. Thus, since the slit width is derived for each combination of different processing depths and surface information, a more appropriate slit width is derived. Therefore, it is possible to appropriately suppress the blocking of the laser light by the structure.

The control unit may control the beam width adjusting unit by further considering an amount of laser incidence position shift on the first surface during processing. It is considered that the processing line is gradually shifted as the processing progresses. In this regard, by specifying such a shift amount in advance and controlling the beam width adjusting unit in consideration of the shift amount, it is possible to suppress the blocking of the laser light by the structure even when the processing line is shifted.

An inspection method according to an aspect of the present invention includes: setting a wafer having a first surface, on which a plurality of elements are formed and a street extends so as to pass between adjacent elements, and a second surface on a side opposite to the first surface; receiving an input of a width of the street and surface information including a position and a height of a structure forming an element adjacent to the street; controlling a beam width adjusting unit that adjusts a beam width of laser light to be equal to or less than a target beam width according to the surface information; and controlling an emission unit that emits laser light so that the laser light is emitted to the wafer from the first surface side.

### Advantageous Effects of Invention

According to an aspect of the present invention, it is possible to perform desired laser emission by suppressing the blocking of laser light by a structure such as a circuit.

### BRIEF DESCRIPTION OF DRAWINGS

FIG. 1 is a configuration diagram of a laser processing device according to an embodiment.

FIG. 2 is a plan view of a wafer of an embodiment.

FIG. 3 is a cross-sectional view of a part of the wafer shown in FIG. 2.

FIG. 4 is a configuration diagram of a laser emission unit shown in FIG. 1.

FIG. 5 is a configuration diagram of an imaging unit for inspection shown in FIG. 1.

FIG. 6 is a configuration diagram of an imaging unit for alignment correction shown in FIG. 1.

FIG. 7 is a cross-sectional view of a wafer for describing the imaging principle of the imaging unit for inspection shown in FIG. 5, and is an image at each location by the imaging unit for inspection.

FIG. 8 is a cross-sectional view of a wafer for describing the imaging principle of the imaging unit for inspection shown in FIG. 5, and is an image at each location by the imaging unit for inspection.

FIG. 9 is SEM images of a modified region and a crack formed inside a semiconductor substrate.

FIG. 10 is SEM images of a modified region and a crack formed inside a semiconductor substrate.

FIG. 11 is an optical path diagram for describing the imaging principle of the imaging unit for inspection shown in FIG. 5, and is a schematic diagram showing an image at a focal point by the imaging unit for inspection.

FIG. 12 is an optical path diagram for describing the imaging principle of the imaging unit for inspection shown in FIG. 5, and is a schematic diagram showing an image at a focal point by the imaging unit for inspection.

FIG. 13 is a diagram describing the adjustment of a beam width.

FIG. 14 is a diagram describing the adjustment of a beam width.

FIG. 15 is a diagram describing the adjustment of a beam width using a slit pattern.

FIG. 16 is a diagram showing a procedure of slit width derivation processing.

FIG. 17 is a diagram showing a procedure of slit width derivation processing.

FIG. 18 is a diagram describing a laser incidence position shift.

FIG. 19 is a flowchart of a beam width adjustment process.

FIG. 20 is a screen image diagram relevant to slit width derivation processing.

### DESCRIPTION OF EMBODIMENTS

Hereinafter, an embodiment of the present invention will be described in detail with reference to the diagrams. In addition, the same or equivalent portions in the diagrams are denoted by the same reference numerals, and repeated description thereof will be omitted. [Configuration of a laser processing device]

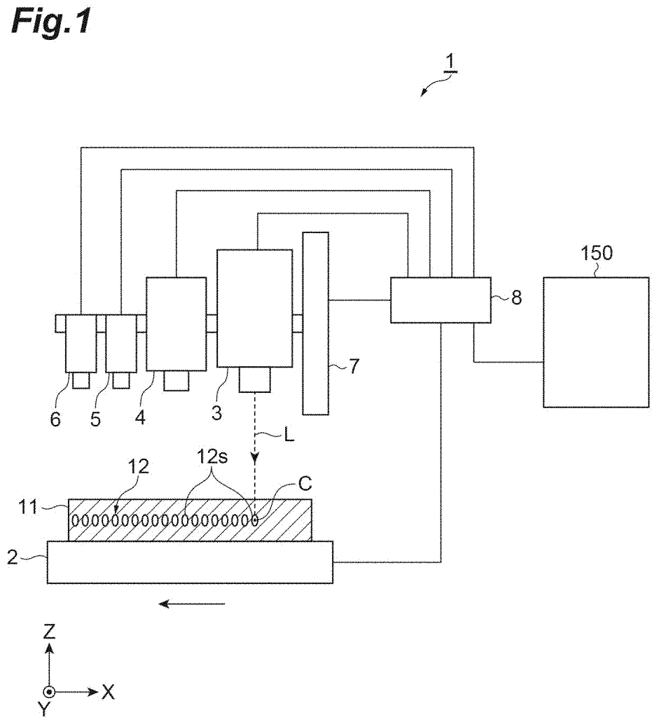

As shown in FIG. 1, a laser processing device 1 includes a stage 2, a laser emission unit 3, a plurality of imaging units 4, 5, and 6, a drive unit 7, a control unit 8, and a display 150. The laser processing device 1 is a device that forms a modified region 12 in an object 11 by emitting laser light L to the object 11.

The stage 2 supports the object 11, for example, by adsorbing a film attached to the object 11. The stage 2 can move along each of the X direction and the Y direction, and can rotate with an axis parallel to the Z direction as a center line. In addition, the X direction and the Y direction are a first horizontal direction and a second horizontal direction perpendicular to each other, and the Z direction is a vertical direction.

The laser emission unit 3 condenses the laser light L, which penetrates the object 11, and emits the laser light L to the object 11. When the laser light L is condensed inside the object 11 supported by the stage 2, the laser light L is particularly absorbed at a portion corresponding to a condensing point C of the laser light L and accordingly, the modified region 12 is formed inside the object 11.

The modified region 12 is a region whose density, refractive index, mechanical strength, and other physical properties are different from those of the surrounding non-modified region. Examples of the modified region 12 include a melt processing region, a crack region, a dielectric breakdown region, and a refractive index change region. The modified region 12 has a characteristic that cracks easily extend from the modified region 12 to the incidence side of the laser light L and the opposite side thereof. Such characteristics of the modified region 12 are used to cut the object 11.

As an example, when the stage 2 is moved along the X direction to move the condensing point C relative to the object 11 along the X direction, a plurality of modified spots 12s are formed so as to be arranged in a row along the X direction. One modified spot 12s is formed by the emission of one-pulse laser light L. The modified region 12 in one row is a set of a plurality of modified spots 12s arranged in one row. The modified spots 12s adjacent to each other may be connected to each other or separated from each other depending on the relative moving speed of the condensing point C with respect to the object 11 and the repetition frequency of the laser light L.

The imaging unit 4 images the modified region 12 formed in the object 11 and the distal end of a crack extending from the modified region 12.

Under the control of the control unit 8, the imaging unit 5 and the imaging unit 6 image the object 11 supported by the stage 2 with the light transmitted through the object 11. As an example, the images obtained by the imaging units 5 and 6 are provided for alignment of the emission position of the laser light L.

The drive unit 7 supports the laser emission unit 3 and a plurality of imaging units 4, 5, and 6. The drive unit 7 moves the laser emission unit 3 and the plurality of imaging units 4, 5, and 6 along the Z direction.

The control unit 8 controls the operations of the stage 2, the laser emission unit 3, the plurality of imaging units 4, 5, and 6, and the drive unit 7. The control unit 8 is configured as a computer device including a processor, a memory, a storage, a communication device, and the like. In the control unit 8, the processor executes software (program) read into the memory or the like to control reading and writing of data in the memory and the storage and communication by the communication device.

The display 150 has a function as an input unit for receiving the input of information from the user and a function as a display unit for displaying information for the user.

[Configuration of an Object]

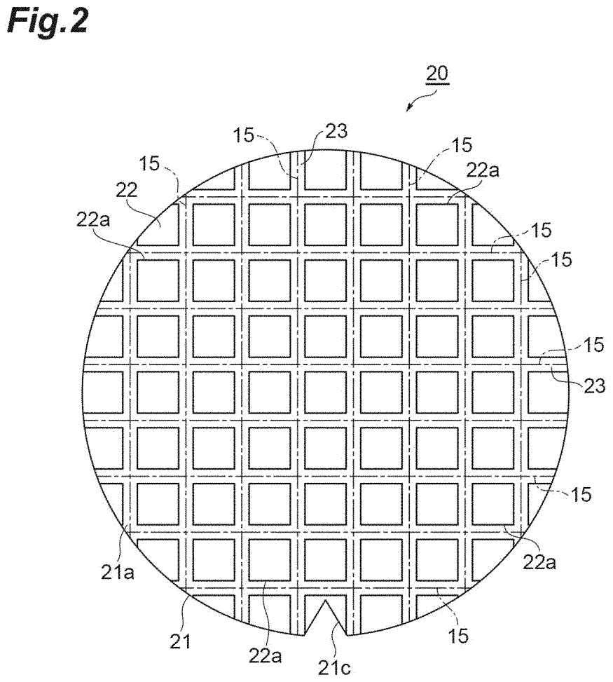

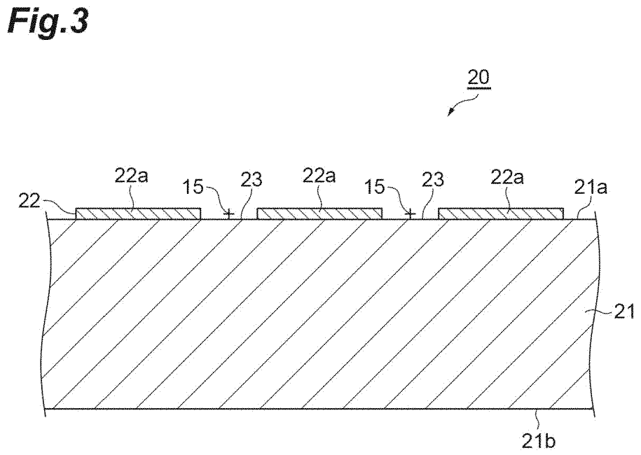

The object 11 of the present embodiment is a wafer 20 as shown in FIGS. 2 and 3. The wafer 20 includes a semiconductor substrate 21 and a functional element layer 22. The semiconductor substrate 21 has a front surface 21a (first surface) and a back surface 21b (second surface). The semiconductor substrate 21 is, for example, a silicon substrate. The functional element layer 22 is formed on the front surface 21a of the semiconductor substrate 21. The functional element layer 22 includes a plurality of functional elements 22a (elements) arranged in a two-dimensional manner along the front surface 21a. Examples of the functional element 22a include a light receiving element such as a photodiode, a light emitting element such as a laser diode, and a circuit element such as a memory. The functional element 22a may be configured in a three-dimensional manner by stacking a plurality of layers. In addition, although a notch 21c indicating the crystal orientation is provided in the semiconductor substrate 21, an orientation flat may be provided instead of the notch 21c.

The wafer 20 is cut along each of a plurality of lines 15 for each functional element 22a. The plurality of lines 15 pass between the plurality of functional elements 22a when viewed from the thickness direction of the wafer 20. More specifically, the line 15 passes through the center (center in the width direction) of a street region 23 (street) when viewed from the thickness direction of the wafer 20. The street region 23 extends so as to pass between the adjacent functional elements 22a in the functional element layer 22. In the present embodiment, the plurality of functional elements 22a are arranged in a matrix along the front surface 21a, and the plurality of lines 15 are set in a grid pattern. In addition, although the line 15 is a virtual line, the line 15 may be a line actually drawn. As described above, the wafer 20 is a wafer having the front surface 21a (see FIG. 2) on which the plurality of functional elements 22a are formed and the street region 23 extends so as to pass between the adjacent functional elements 22a and the back surface 21b (see FIG. 3) on a side opposite to the front surface 21a.

[Configuration of a Laser Emission Unit]

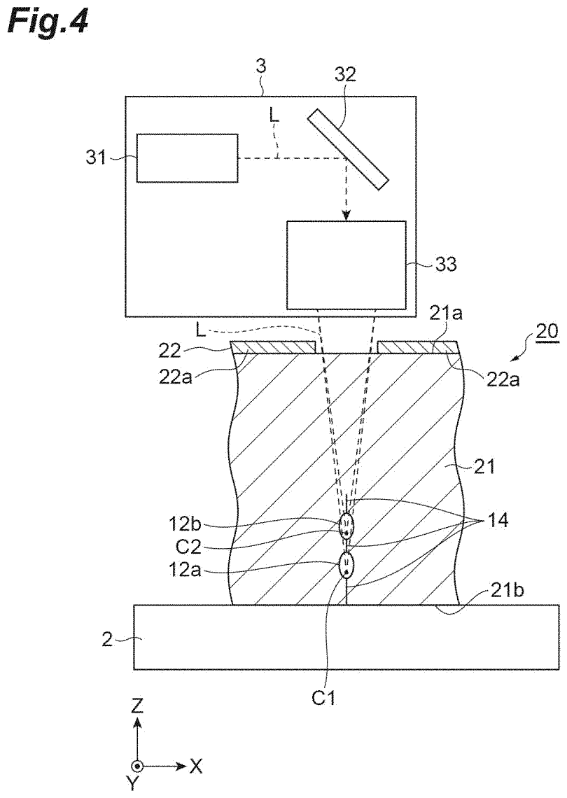

As shown in FIG. 4, the laser emission unit 3 includes a light source 31 (emission unit), a spatial light modulator 32 (beam width adjusting unit), and a condenser lens 33. The light source 31 outputs the laser light L by using, for example, a pulse oscillation method. The light source 31 emits laser light to the wafer 20 from the front surface 21a side to form a plurality (here, two rows) of modified regions 12a and 12b inside the wafer 20. The spatial light modulator 32 modulates the laser light L output from the light source 31. The spatial light modulator 32 functions as a slit portion for adjusting the beam width of the laser light by blocking a part of the laser light (details will be described later). The slit portion as a function of the spatial light modulator 32 is a slit pattern that is set as a modulation pattern of the spatial light modulator 32. In the spatial light modulator 32, a modulation pattern displayed on the liquid crystal layer is appropriately set, so that the laser light L can be modulated (for example, the intensity, amplitude, phase, polarization, and the like of the laser light L can be modulated). The modulation pattern is a hologram pattern for modulation, and includes a slit pattern. The spatial light modulator 32 is, for example, a spatial light modulator (SLM) of a liquid crystal on silicon (LCOS). The condenser lens 33 condenses the laser light L modulated by the spatial light modulator 32. In addition, the condenser lens 33 may be a correction ring lens.

In the present embodiment, the laser emission unit 3 emits the laser light L to the wafer 20 from the front surface 21a side of the semiconductor substrate 21 along each of the plurality of lines 15, so that two rows of modified regions 12a and 12b are formed inside the semiconductor substrate 21 along each of the plurality of lines 15. The modified region 12a is a modified region closest to the back surface 21b among the two rows of modified regions 12a and 12b. The modified region 12b is a modified region closest to the modified region 12a and is a modified region closest to the front surface 21a among the two rows of modified regions 12a and 12b.

The two rows of modified regions 12a and 12b are adjacent to each other in the thickness direction (Z direction) of the wafer 20. The two rows of modified regions 12a and 12b are formed by moving two condensing points C1 and C2 relative to the semiconductor substrate 21 along the line 15. The laser light L is modulated by the spatial light modulator 32 so that, for example, the condensing point C2 is located behind the condensing point C1 in the traveling direction and on the incidence side of the laser light L. In addition, regarding the formation of a modified region, single focusing or multifocusing may be applied, or one pass or a plurality of passes may be applied.

The laser emission unit 3 emits the laser light L to the wafer 20 from the front surface 21a side of the semiconductor substrate 21 along each of the plurality of lines 15. As an example, for the semiconductor substrate 21 that is a single crystal silicon <100> substrate having a thickness of 400 μm, two condensing points C1 and C2 are aligned at a position of 54 μm and a position of 128 μm from the back surface 21b, and the laser light L is emitted to the wafer 20 from the front surface 21a side of the semiconductor substrate 21 along each of the plurality of lines 15. At this time, for example, when the condition is that a crack 14 extending over the two rows of modified regions 12a and 12b reaches the back surface 21b of the semiconductor substrate 21, the wavelength of the laser light L is 1099 nm, the pulse width is 700 nsec, and the repetition frequency is 120 kHz. In addition, the output of the laser light L at the condensing point C1 is 2.7 W, the output of the laser light L at the condensing point C2 is 2.7 W, and the relative moving speed of the two condensing points C1 and C2 with respect to the semiconductor substrate 21 is 800 mm/sec. In addition, the laser light L may be emitted under the condition that the crack 14 extending over the two rows of modified regions 12a and 12b do not reach the back surface 21b of the semiconductor substrate 21. That is, in a later step, for example, the crack 14 may be exposed on the back surface 21b while thinning the semiconductor substrate 21 by grinding the back surface 21b of the semiconductor substrate 21, and the wafer 20 may be cut into a plurality of semiconductor devices along each of the plurality of lines 15.

[Configuration of an Imaging Unit for Inspection]

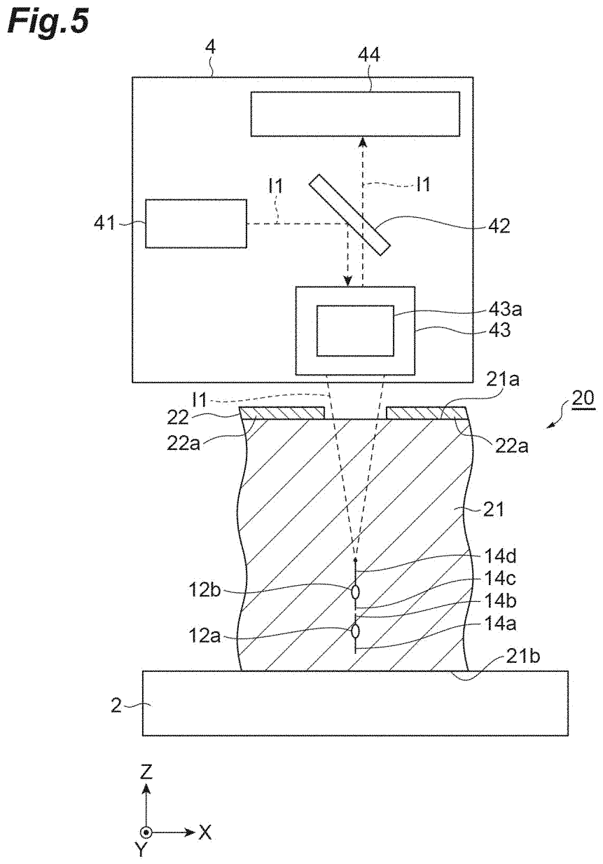

As shown in FIG. 5, the imaging unit 4 includes a light source 41, a mirror 42, an objective lens 43, and a photodetector 44. The imaging unit 4 images the wafer 20. The light source 41 outputs light I1, which penetrates the semiconductor substrate 21. The light source 41 is configured to include, for example, a halogen lamp and a filter, and outputs the light I1 in the near infrared region. The light I1 output from the light source 41 is reflected by the mirror 42, passes through the objective lens 43, and is emitted to the wafer 20 from the front surface 21a side of the semiconductor substrate 21. At this time, the stage 2 supports the wafer 20 in which the two rows of modified regions 12a and 12b are formed as described above.

The objective lens 43 allows the light I1 reflected by the back surface 21b of the semiconductor substrate 21 to pass therethrough. That is, the objective lens 43 allows the light I1 that has propagated through the semiconductor substrate 21 to pass therethrough. The numerical aperture (NA) of the objective lens 43 is, for example, 0.45 or more. The objective lens 43 has a correction ring 43a. The correction ring 43a corrects the aberration occurring in the light I1 within the semiconductor substrate 21, for example, by adjusting the distance between a plurality of lenses forming the objective lens 43. In addition, the means for correcting the aberration is not limited to the correction ring 43a, and may be another correction means such as a spatial light modulator. The photodetector 44 detects the light I1 that has passed through the objective lens 43 and the mirror 42. The photodetector 44 is, for example, an InGaAs camera, and detects the light I1 in the near infrared region. In addition, the means for detecting (imaging) the light I1 in the near infrared region is not limited to the InGaAs camera, and other imaging means may be used as long as it is possible to perform transmissive imaging such as a transmissive confocal microscope.

The imaging unit 4 can image the distal ends of the two rows of modified regions 12a and 12b and the distal ends of a plurality of crack 14a, 14b, 14c, and 14d. The crack 14a is a crack extending from the modified region 12a to the back surface 21b side. The crack 14b is a crack extending from the modified region 12a to the front surface 21a side. The crack 14c is a crack extending from the modified region 12b to the back surface 21b side. The crack 14d is a crack extending from the modified region 12b to the front surface 21a side.

[Configuration of an Imaging Unit for Alignment Correction]

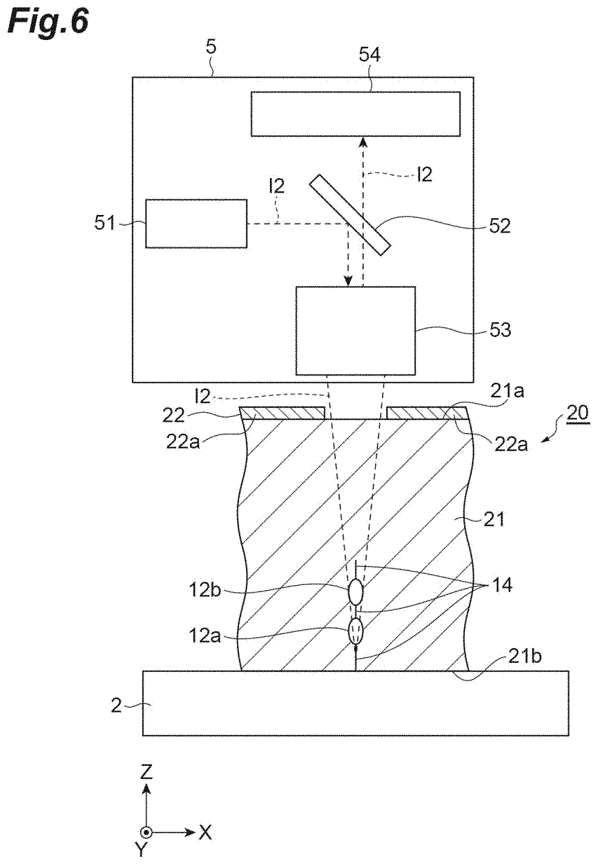

As shown in FIG. 6, the imaging unit 5 includes a light source 51, a mirror 52, a lens 53, and a photodetector 54. The light source 51 outputs light 12, which penetrates the semiconductor substrate 21. The light source 51 is configured to include, for example, a halogen lamp and a filter, and outputs the light 12 in the near infrared region. The light source 51 may be shared with the light source 41 of the imaging unit 4. The light 12 output from the light source 51 is reflected by the mirror 52, passes through the lens 53, and is emitted to the wafer 20 from the front surface 21a side of the semiconductor substrate 21.

The lens 53 allows the light 12 reflected by the back surface 21b of the semiconductor substrate 21 to pass therethrough. That is, the lens 53 allows the light 12 that has propagated through the semiconductor substrate 21 to pass therethrough. The numerical aperture of the lens 53 is 0.3 or less. That is, the numerical aperture of the objective lens 43 of the imaging unit 4 is larger than the numerical aperture of the lens 53. The photodetector 54 detects the light 12 that has passed through the lens 53 and the mirror 52. The photodetector 54 is, for example, an InGaAs camera, and detects the light 12 in the near infrared region.

Under the control of the control unit 8, the imaging unit 5 emits the light 12 to the wafer 20 from the front surface 21a side and detects the light 12 returning from the back surface 21b side, thereby imaging the back surface 21b. Similarly, under the control of the control unit 8, the imaging unit 5 emits the light 12 to the wafer 20 from the front surface 21a side and detects the light 12 returning from the formation positions of the modified regions 12a and 12b in the semiconductor substrate 21, thereby acquiring an image of a region including the modified regions 12a and 12b. These images are used for alignment of the emission position of the laser light L. The imaging unit 6 has the same configuration as the imaging unit 5 except that the lens 53 has a lower magnification (for example, 6 times in the imaging unit 5 and 1.5 times in the imaging unit 6), and is used for alignment similarly to the imaging unit 5.

[Imaging Principle of an Imaging Unit for Inspection]

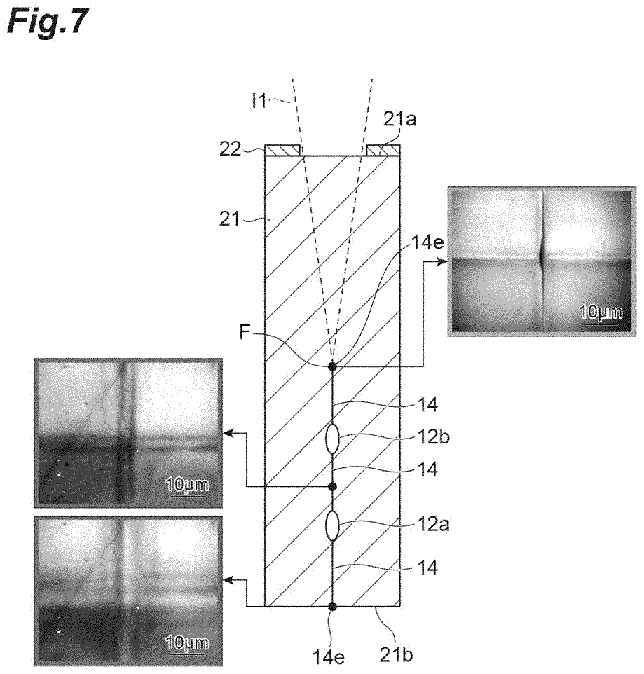

By using the imaging unit 4 shown in FIG. 5, as shown in FIG. 7, for the semiconductor substrate 21 in which the crack 14 extending over the two rows of modified regions 12a and 12b reaches the back surface 21b, a focus F (focus of the objective lens 43) is moved from the front surface 21a side to the back surface 21b side. In this case, by adjusting the focus F to the distal end 14e of the crack 14, which extends from the modified region 12b to the front surface 21a side, from the front surface 21a side, it is possible to check the distal end 14e (image on the right side in FIG. 7). However, even if the focus F is adjusted from the front surface 21a side to the crack 14 itself and the distal end 14e of the crack 14 reaching the back surface 21b, it is not possible to check these (image on the left side in FIG. 7).

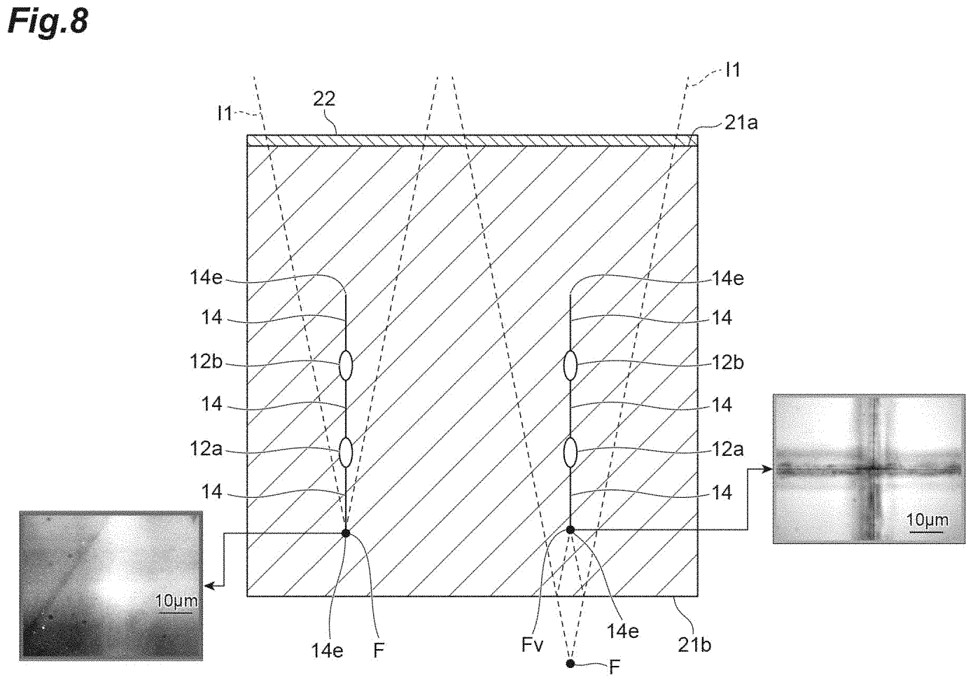

In addition, by using the imaging unit 4 shown in FIG. 5, as shown in FIG. 8, for the semiconductor substrate 21 in which the crack 14 extending over the two rows of modified regions 12a and 12b does not reach the back surface 21b, the focus F is moved from the front surface 21a side to the back surface 21b side. In this case, even if the focus F is adjusted from the front surface 21a side to the distal end 14e of the crack 14 extending from the modified region 12a to the back surface 21b side, it is not possible to check the distal end 14e (image on the left side in FIG. 8). However, when the focus F is adjusted from the front surface 21a side to a region opposite to the front surface 21a with respect to the back surface 21b so that a virtual focus Fv symmetrical with the focus F with respect to the back surface 21b is located at the distal end 14e, it is possible to check the distal end 14e (image on the right side in FIG. 8). In addition, the virtual focus Fv is a point symmetrical with the focus F considering the refractive index of the semiconductor substrate 21 with respect to the back surface 21b.

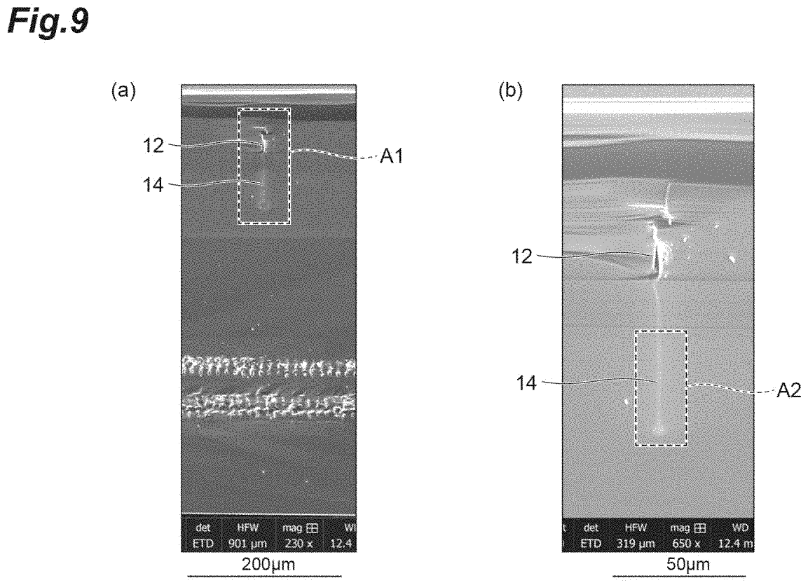

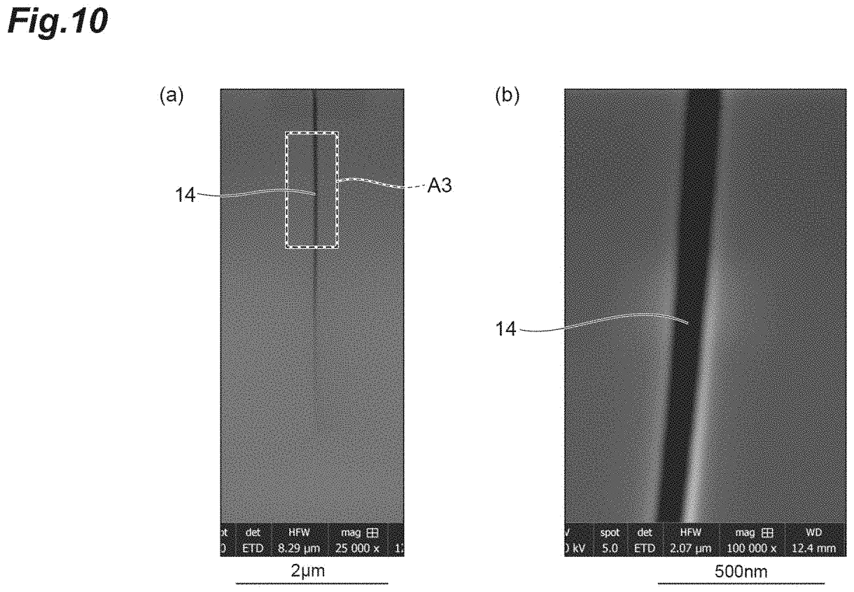

It is presumed that the reason why the crack 14 itself cannot be checked as described above is that the width of the crack 14 is smaller than the wavelength of the light I1 that is illumination light. FIGS. 9 and 10 are SEM (Scanning Electron Microscope) images of the modified region 12 and the crack 14 formed inside the semiconductor substrate 21 that is a silicon substrate. FIG. 9(b) is an enlarged image of a region A1 shown in FIG. 9(a), FIG. 10(a) is an enlarged image of a region A2 shown in FIG. 9(b), and FIG. 10(b) is an enlarged image of a region A3 shown in FIG. 10(a). As described above, the width of the crack 14 is about 120 nm, which is smaller than the wavelength (for example, 1.1 to 1.2 μm) of the light I1 in the near infrared region.

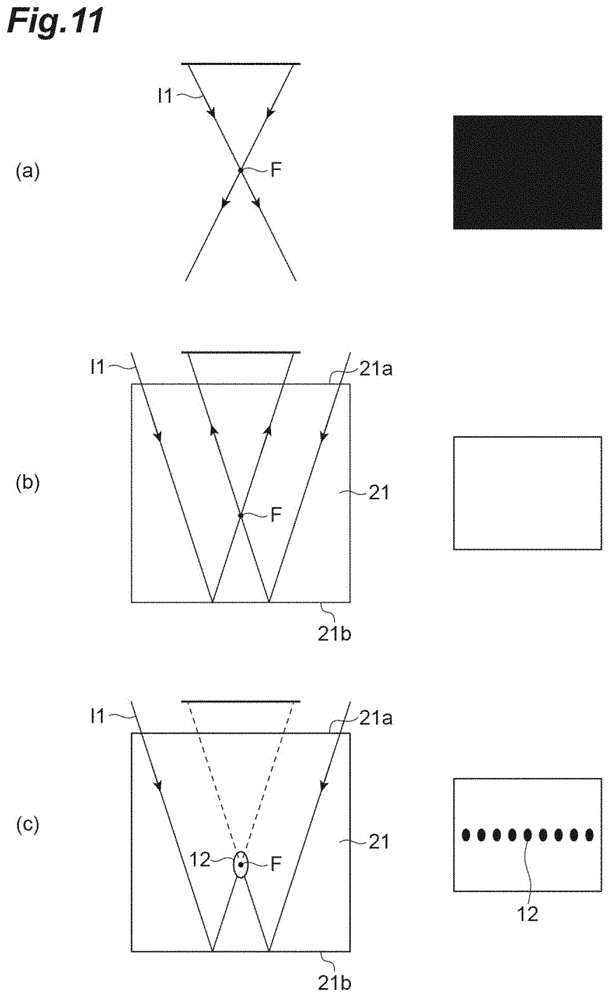

The imaging principle assumed based on the above is as follows. As shown in FIG. 11(a), when the focus F is located in the air, the light I1 does not return, so that a blackish image is obtained (image on the right side in FIG. 11(a)). As shown in FIG. 11(b), when the focus F is located inside the semiconductor substrate 21, the light I1 reflected by the front surface 21a is returned, so that a whitish image is obtained (image on the right side in FIG. 11(b)). As shown in FIG. 11(c), when the focus F is adjusted from the front surface 21a side to the modified region 12, absorption, scattering, and the like of a part of the light I1 that is reflected by the back surface 21b and returned occur due to the modified region 12, so that an image is obtained in which the modified region 12 appears blackish in a whitish background (image on the right side in FIG. 11(c)).

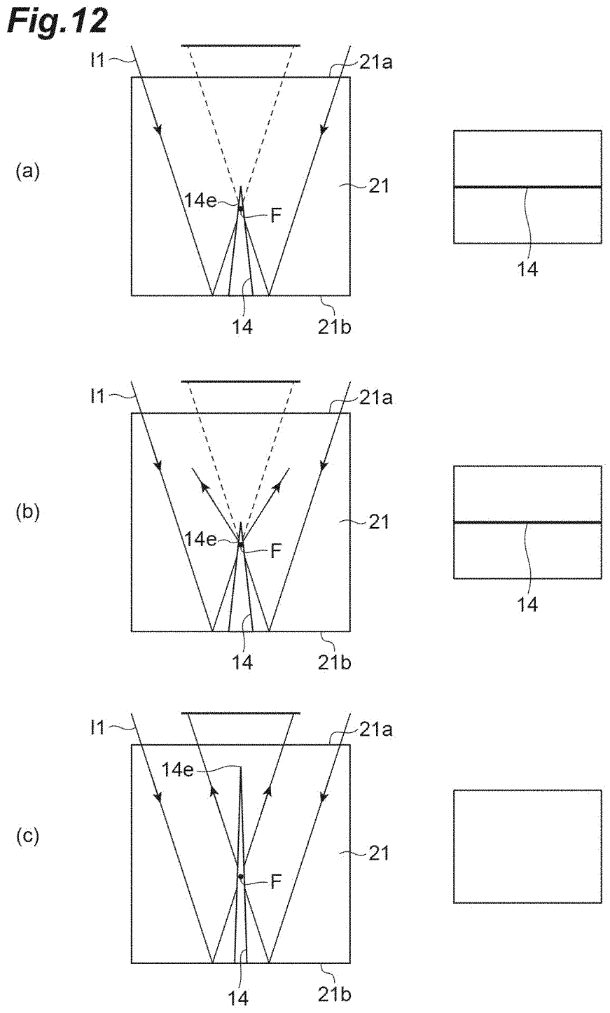

As shown in FIGS. 12(a) and 12(b), when the focus F is adjusted from the front surface 21a side to the distal end 14e of the crack 14, scattering, reflection, interference, absorption, and the like of a part of the light I1 that is reflected by the back surface 21b and returned occur due to, for example, optical specificity (stress concentration, strain, discontinuity of atomic density, and the like) occurring near the distal end 14e, confinement of light occurring near the distal end 14e, and the like, so that an image is obtained in which the distal end 14e appears blackish in a whitish background (images on the right side in FIGS. 12(a) and 12(b)). As shown in FIG. 12(c), when the focus F is adjusted from the front surface 21a side to a portion other than the vicinity of the distal end 14e of the crack 14, at least a part of the light I1 reflected by the back surface 21b is returned, so that a whitish image is obtained (image on the right side in FIG. 12(c)).

[Process for Adjusting the Beam Width of Laser Light]

Hereinafter, a process for adjusting the beam width of laser light, which is performed when performing a process for forming a modified region for the purpose of cutting and the like of the wafer 20, will be described. In addition, the beam width adjustment process may be performed separately from the process for forming a modified region (without being associated with the process for forming a modified region).

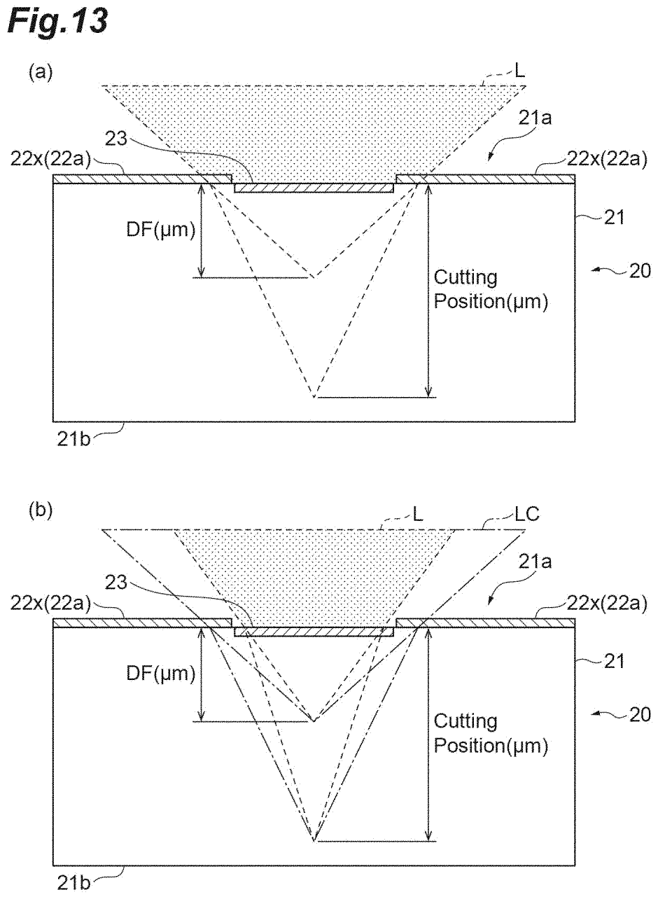

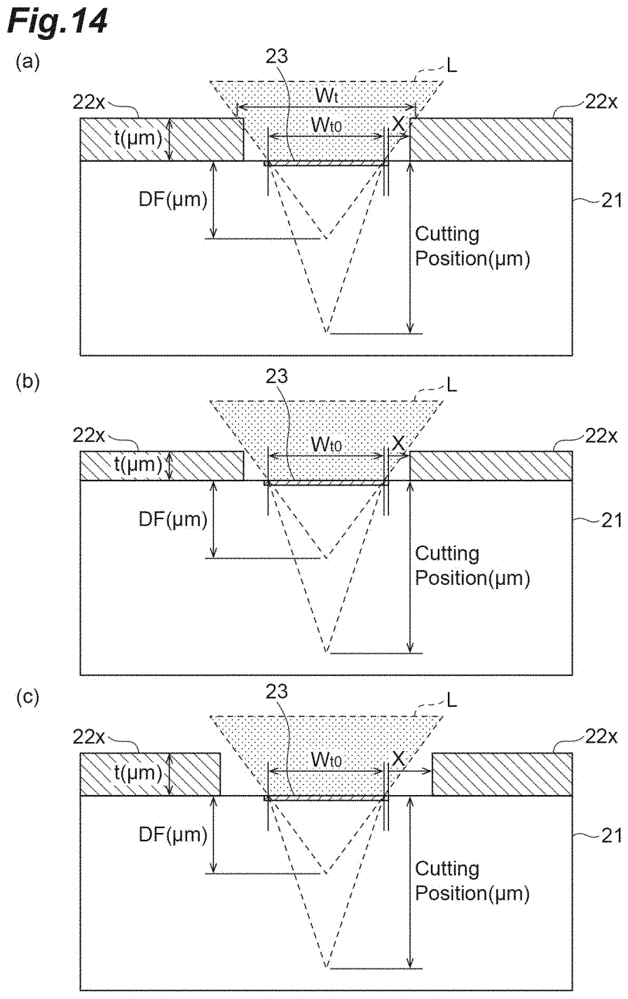

First, the reason why it is necessary to adjust the beam width of the laser light will be described with reference to FIGS. 13 and 14. FIGS. 13 and 14 are diagrams illustrating the adjustment of the beam width. In addition, in each diagram of FIGS. 13 and 14 and the like, “DF” indicates a processing position (condensing position) by laser light, and “Cutting Position” indicates a cutting position when the back surface 21b is polished to cut the wafer 20 into a plurality of semiconductor devices in a later step. As shown in FIG. 13, a plurality of functional elements 22a are formed on the front surface 21a that is the incidence surface of the laser light L in the wafer 20 of the present embodiment. As shown in FIG. 13(a), when the beam width of the laser light L is large, the laser light L incident on the front surface 21a protrudes from the street region 23 and reaches the functional element 22a, so that a part of the laser light L is not condensed inside the wafer 20 (is blocked by the functional element 22a). When the street region 23 is narrow or the processing position (condensing position) is deep, the situation in which the laser light L is blocked by the functional element 22a is likely to occur. When the laser light L is blocked by the functional element 22a, a part of the laser light L is not condensed inside the wafer 20, so that the output of the laser light L inside the wafer 20 is reduced. In addition, due to the interference between the laser light L and the functional element 22a, an undesirable beam may enter the inside of the wafer 20 to degrade the processing quality. In addition, depending on a structure 22x that forms the functional element 22a, there is a possibility that the structure 22x will be melted by the emission of the laser light L.

In order to avoid the situation in which the laser light L is blocked by the functional element 22a, it is necessary to adjust the beam width of the laser light L. For example, by cutting the laser light L to an arbitrary width using a slit portion (slit pattern set as a modulation pattern) of the spatial light modulator 32 (details will be described later), the laser light L incident on the front surface 21a can be confined within the width of the street region 23 as shown in FIG. 13(b). That is, by cutting a part of the laser light L (laser light cut portion LC), the laser light L incident on the front surface 21a can be confined within the width of the street region 23.

Here, the structure 22x that forms the functional element 22a has a predetermined height t (thickness t). For this reason, even if the laser light L can be confined within the street region 23 as described above, the laser light L may be blocked by a part of the structure 22x having the height t. For example, in an example shown in FIG. 14(a), the beam width Wt0 of the laser light L is controlled to be smaller than the width of the street region 23 on the surface where the laser light L is incident on the street region 23. However, the structures 22x and 22x having the height t are provided at positions (positions X) separated from both ends of the street region 23 by a distance X, and the beam width Wt of the laser light L at the position of the height t is larger than the separation distance between the structures 22x and 22x, so that the laser light L is blocked by a part of each structure 22x having the height t.

On the other hand, for example, as shown in FIG. 14(b), when the height t of each of the structures 22x and 22x is sufficiently smaller than the height t of each of the structures 22x and 22x shown in FIG. 14(a) described above, even if the conditions such as the beam width Wt0 of the laser light L and the distance X of each of the structures 22x and 22x from the end of the street region 23 are the same as those shown in FIG. 14(a), the situation in which the laser light L is blocked by the structure 22x forming the functional element 22a does not occur. In addition, for example, as shown in FIG. 14(c), when the distance X of each of the structures 22x and 22x from the end of the street region 23 is sufficiently larger than the distance X of each of the structures 22x and 22x from the end of the street region 23 shown in FIG. 14(a) described above, even if the conditions such as the beam width Wt0 of the laser light L and the height t of each of the structures 22x and 22x are the same as those shown in FIG. 14(a), the situation in which the laser light L is blocked by the structure 22x forming the functional element 22a does not occur.

As described above, in order to suppress the occurrence of the situation in which the laser light L is blocked by the structure 22x forming the functional element 22a, it is necessary to adjust the beam width of the laser light L in consideration of the position and height of the structure 22x forming the functional element 22a adjacent to the street region 23 in addition to the width of the street region 23. Hereinafter, the detailed functions of the control unit 8 relevant to the beam width adjustment of laser light will be described.

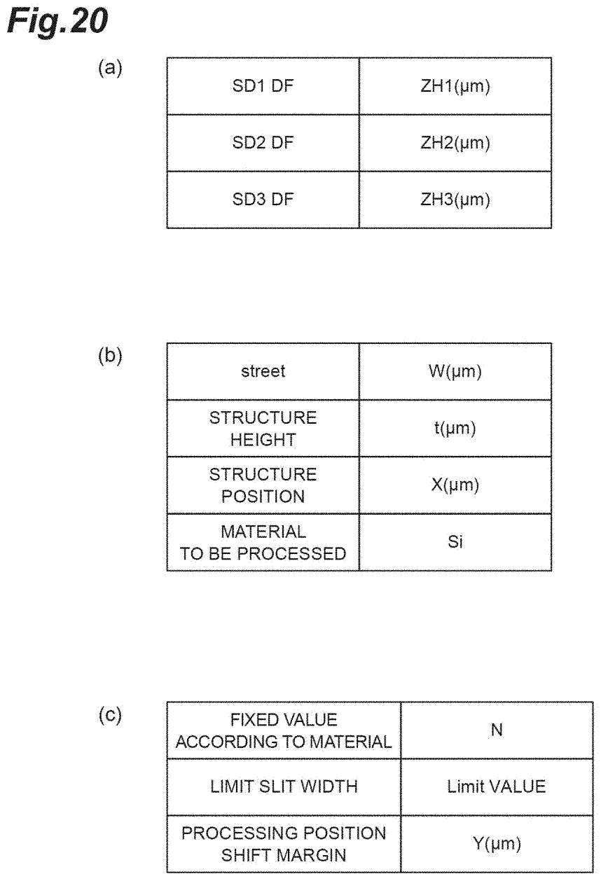

The control unit 8 controls the spatial light modulator 32 (beam width adjusting unit) so that the beam width of the laser light is adjusted to be equal to or less than the width of the street region 23 and a target beam width according to surface information including the position and height of the structure 22x forming the functional element 22a adjacent to the street region 23. For example, based on information input to the user on a setting screen (see FIG. 20(b)) displayed on the display 150, the control unit 8 acquires the width W of the street region 23 and the surface information including the position X and the height t of the structure 22x forming the functional element 22a adjacent to the street region 23. The position X of the structure 22x is the separation distance X from the end of the street region 23 to the structure 22x. The target beam width is a value on the front surface 21a and a value at the height t of the structure 22x. The target beam width on the front surface 21a is, for example, the width W of the street region 23. The target beam width at the height t of the structure 22x is, for example, a separation distance between the structures 22x and 22x adjacent to the street region 23, and is a value (W+X+X) obtained by adding up the width W of the street region 23, the position X of one structure 22x, and the position X of the other structure 22x. Since the beam width of the laser light on the front surface 21a is controlled to be equal to or less than the target beam width on the front surface 21a and the beam width of the laser light at the height t is controlled to be equal to or less than the target beam width at the height t, the laser light can be reliably confined within the street region 23, and it is possible to avoid the situation in which the laser light L is blocked by the structure 22x forming the functional element 22a.

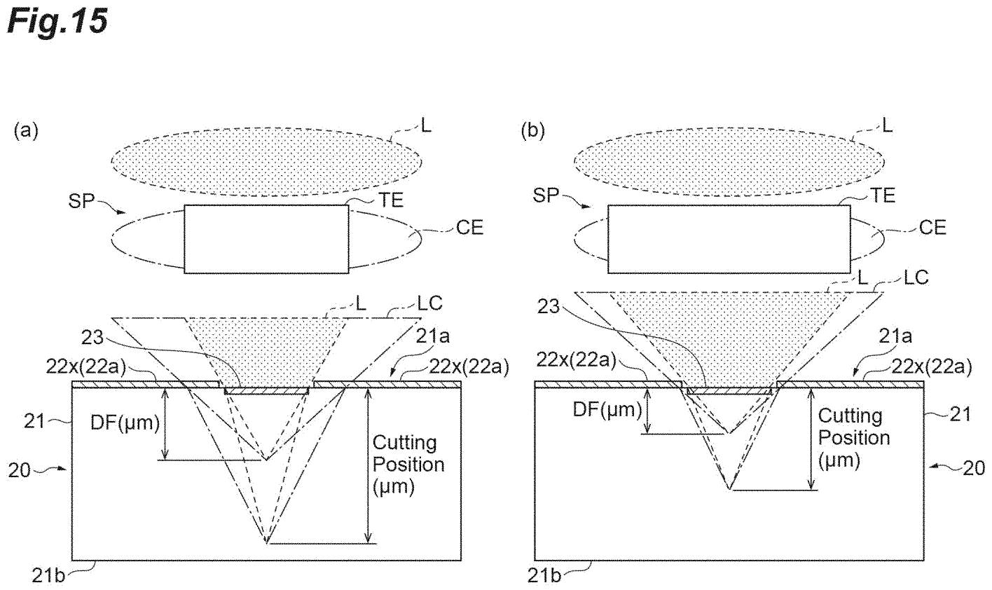

Based on the surface information described above, the control unit 8 derives a slit width relevant to the laser light transmission region in the spatial light modulator 32 that functions as a slit portion (details will be described later), and sets a slit pattern corresponding to the slit width in the spatial light modulator 32. FIG. 15 is a diagram describing the adjustment of the beam width using a slit pattern SP. The slit pattern SP shown in FIG. 15(a) is a modulation pattern displayed on the liquid crystal layer of the spatial light modulator 32. The slit pattern SP includes a cutoff region CE that blocks the laser light L and a transmission region TE that transmits the laser light L. The transmission region TE is set to a size corresponding to the slit width. The slit pattern SP is set so that the smaller the slit width, the smaller the transmission region TE (the larger the cutoff region CE) and the larger the laser light cut portion LC. In the slit pattern SP of FIG. 15(a), in order to reduce the beam width of the laser light L, both end portions of the laser light L in the width direction thereof are set as the cutoff regions CE and the central region is set as the transmission region TE. As shown in FIG. 15(a), since the laser light passes through the slit pattern SP, both end portions (laser light cut portions LC) of the laser light L in the width direction are cut, so that the beam width of the laser light L can be made to be equal to or less than the target beam width.

The control unit 8 may derive the slit width by further considering the processing depth of the laser light L in the wafer 20. FIG. 15(b) shows an example in which the processing depth (position of “DF”) is smaller than that in FIG. 15(a) described above. In FIGS. 15(a) and 15(b), it is assumed that other conditions such as surface information are the same. In this case, for the slit pattern SP in FIG. 15(b) having a small processing depth, the control unit 8 reduces the cutoff region CE and increases the transmission region TE as compared with the slit pattern SP in FIG. 15(a) having a large processing depth. That is, the control unit 8 may increase the cutoff region CE in the slit pattern SP as the processing depth of the laser light L decreases. Therefore, it is possible to set the slit pattern SP more appropriately in consideration of the processing depth in addition to the surface information. For example, as shown in FIG. 4, when a plurality (two rows) of modified regions 12a and 12b are formed at different depths inside the semiconductor substrate 21, the control unit 8 may derive the slit width for each combination of surface information and the processing depth of the laser light L.

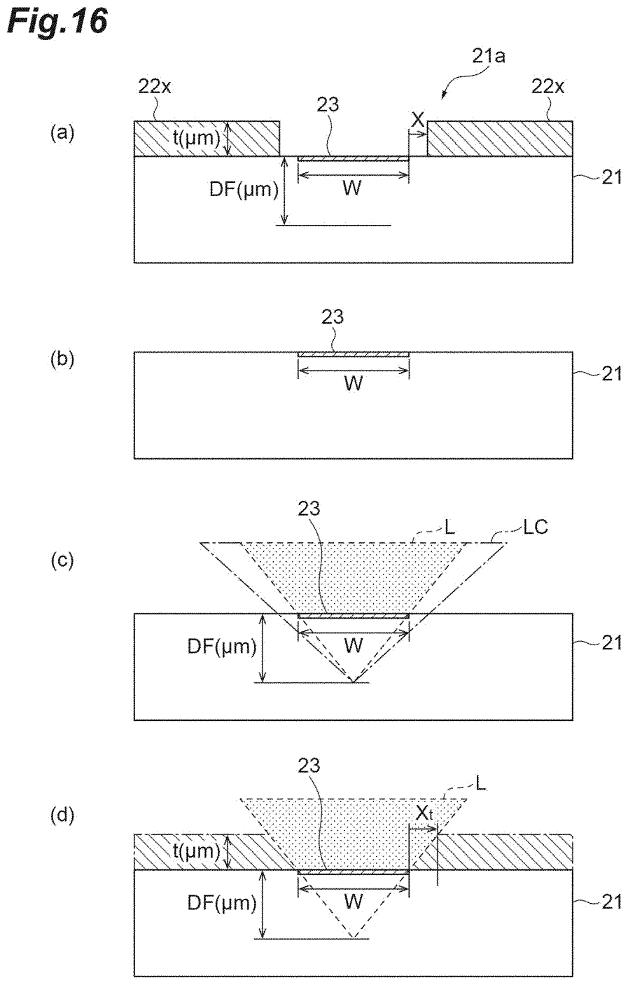

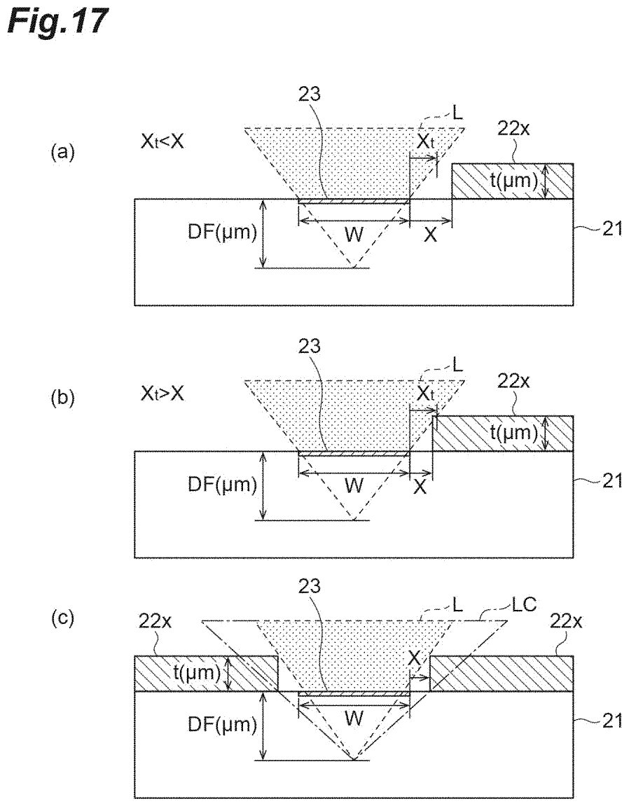

FIGS. 16 and 17 are diagrams illustrating an example of a specific slit width derivation process. The control unit 8 derives the slit width by performing the following calculations of procedures 1 to 4, for example. In addition, as will be described later, the calculation procedures of the control unit 8 are not limited to those described below.

As shown in FIG. 16(a), it is assumed that the width of the street region 23 of the wafer 20 is W, the position (distance from the end of the street region 23) of each of the structures 22x and 22x is X, the height of the structure 22x is t, and the processing depth of the laser light L is DF. In addition, the processing depth is a processing depth from the front surface 21a.

In the procedure 1, as shown in FIGS. 16(b) and 16(c), the control unit 8 ignores the presence of the structure 22x, and calculates the slit width so that the beam width of the laser light is equal to or less than the target beam width (width W of the street region 23) on the front surface 21a. The slit width is derived by the following Equation (1).

$$[ Equation 1 ]$$

$$SLIT = Z \cdot n \cdot sin ( {tan}^{- 1} ( \frac{W}{a \cdot 2 \cdot DF} ) ) \qquad ( 1 )$$

In the above Equation (1), “SLIT” is a slit width, Z is a fixed value determined according to the type of the spatial light modulator 32, n is a refractive index determined according to the material to be processed, and a is a constant (dz rate) considering the refractive index of the material to be processed. Now, it is assumed that n=3.6, a=4.8, Z=480, the width W of the street region 23=20 μm, and the processing depth DF=50 μm. In this case, a slit width SLITstreet based on the width of the street region 23 in the procedure 1=72 μm is derived.

Subsequently, in the procedure 2, as shown in FIG. 16(d), the control unit 8 calculates a distance Xt by which the beam of the laser light spreads from the front surface 21a to the height t of the structure 22x when the slit width SLITstreet=72 μm calculated in the procedure 1 is adopted. The distance Xt is derived by the following Equation (2), which is a modification of Equation (1). Now, it is assumed that the height t of the structure 22x is 40 μm. In this case, by substituting the slit width SLITstreet=72 μm described above into SLIT in Equation (2), the distance Xt=8 μm is derived.

$$[ Equation 2 ]$$

$${X}_{t} = a \cdot t \cdot tan ( {sin}^{- 1} ( \frac{SLIT}{Z \cdot n} ) ) \qquad ( 2 )$$

Subsequently, in the procedure 3, the control unit 8 compares the distance Xt=8 μm derived in the procedure 2 with the position (distance from the end of the street region 23) X of the structure 22x. For example, as shown in FIG. 17(a), when the position X is larger than the distance Xt (the position X is larger than 8 μm), the control unit 8 determines that the laser light is not blocked by the structure 22x even if the slit width SLITstreet=72 μm is adopted, and determines the slit width SLITstreet as a final slit width. On the other hand, for example, as shown in FIG. 17(b), when the position X is smaller than the distance Xt (the position X is smaller than 8 μm), the control unit 8 determines that the laser light is blocked by the structure 22x when the slit width SLITstreet=72 μm is adopted, and determines to recalculate the final slit width in consideration of the position and height of the structure 22x without adopting the slit width SLITstreet.

The procedure 4 is performed only when it is determined that the final slit width considering the position and height of the structure 22x is to be recalculated in the procedure 3. In the procedure 4, as shown in FIG. 17(c), the control unit 8 calculates the slit width so that the beam width of the laser light is equal to or less than the target beam width at the height t of the structure 22x in consideration of the position and height of the structure 22x. The slit width is derived by the following Equation (3). Now, it is assumed that the position (distance from the end of the street region 23) X of the structure 22x=4 μm. In this case, the final slit width SLITstructure=56 μm is derived in consideration of the position and height of the structure 22x.

$$[ Equation 3 ]$$

$$SLIT = Z \cdot n \cdot sin ( {tan}^{- 1} ( \frac{W + X + X}{a \cdot 2 \cdot ( DF + t )} ) ) \qquad ( 3 )$$

In addition, in the calculation procedures described above, the slit width is first calculated by ignoring the presence of the structure 22x, and then it is determined whether or not the laser light is blocked by the structure 22x in the case of the slit width, and the final slit width is derived. However, the calculation procedures are not limited to these. For example, the control unit 8 may derive both the slit width SLITstreet derived by Equation (1) and the slit width SLITstructure derived by Equation (3) and then determine the smaller slit width as a final slit width.

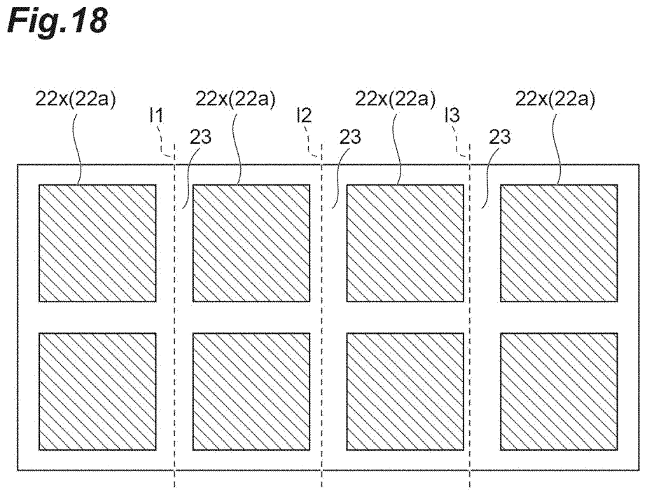

The control unit 8 may control the spatial light modulator 32 for setting a slit pattern by further considering the amount of incidence position shift of laser light on the front surface 21a during processing. As shown in FIG. 18, when laser light is continuously emitted to the street regions 23 of a plurality of processing lines 11 to 13, a gap is generated between the chips, so that the positions of the processing lines 11 to 13 are gradually shifted. In the example of FIG. 18, compared with the processing line 11 processed first, the position of the processing line 12 processed next is shifted to the left side, and compared with the processing line 12, the position of the processing line 13 processed next is shifted to the left side. For example, it is conceivable to perform a correction process once for several processing lines, but it is not possible to eliminate the position shift unless the correction is performed for each processing line. However, it is not practical to perform a correction for each processing line when the processing time is taken into consideration. In the present embodiment, the control unit 8 specifies in advance the amount of incidence position shift (processing position shift margin value) of the laser light during processing, and sets a value considering the processing position shift margin value as the width W of the street region 23 when deriving the slit width using Equation (1) or (3) described above. For example, the control unit 8 may set a value, which is obtained by subtracting the processing position shift margin value from the width W of the street region 23, as the corrected width W of the street region 23 to derive the slit width. Then, the control unit 8 controls the spatial light modulator 32 so that the slit pattern based on the slit width derived in consideration of the processing position shift margin value is set.

When the derived slit width is smaller than the limit slit value that is a limit value that enables the formation of a modified region, the control unit 8 may control the display 150 to display information indicating that processing is not possible. The limit slit value is, for example, a value set for each engine based on prior processing experiments.

When the derived slit width is a slit width that increases the length of a crack extending from the modified region 12, the control unit 8 may control the display 150 to display information for prompting a change in various processing conditions. Examples of the processing conditions include the number of processes, ZH (Z height), VD, the number of focal points, pulse energy, condensing state parameters, processing speed, frequency, and pulse width. ZH is information indicating the processing depth (height) when performing laser processing.

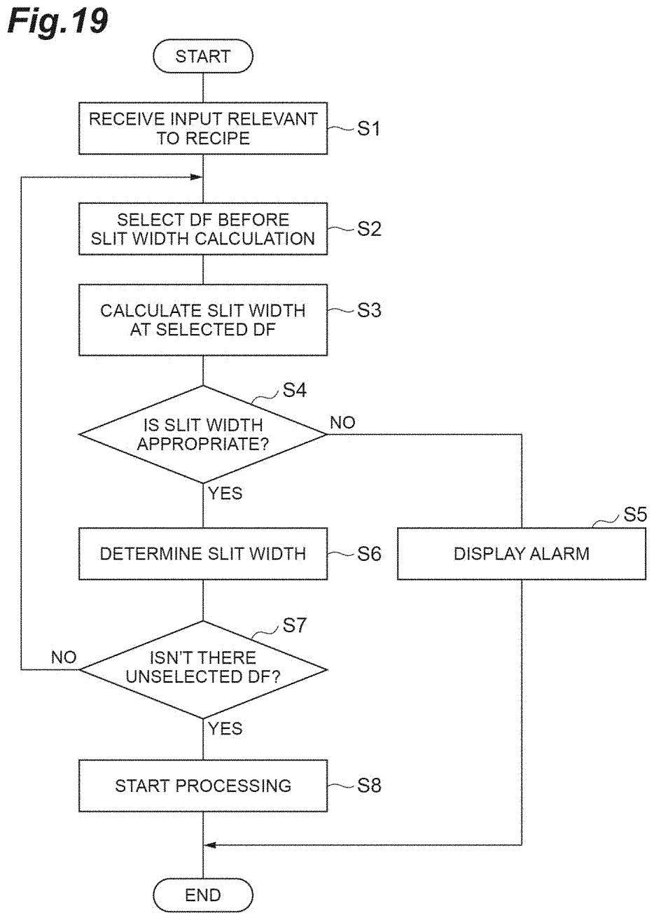

Next, a beam width adjustment process performed by the control unit 8 will be described with reference to FIG. 19.

First, the control unit 8 receives an input relevant to the processing conditions (recipe) (step S1). For example, the control unit 8 receives an input of information from the user through a setting screen displayed on the display 150. Specifically, as shown in FIG. 20(a), the control unit 8 receives an input of Z heights (ZH1, ZH2, ZH3) at the processing positions of a plurality of modified regions 12 (SD1, SD2, SD3 in FIG. 20). In addition, as shown in FIG. 20(c), the control unit 8 receives an input of the width W of the street region 23, the height t of the structure 22x, the position X of the structure 22x, and a material to be processed (for example, silicon). In addition, the control unit 8 acquires a fixed value set in advance instead of the input from the user.

Specifically, as shown in FIG. 20(b), the control unit 8 acquires a fixed value N according to a material (for example, a fixed value corresponding to n and a in Equation (1)), a limit slit width (limit slit value), and a processing position shift margin Y. In addition, these values may or may not be displayed on the display 150. In addition, these values may be set by the input from the user when displayed on the display 150.

Subsequently, the control unit 8 selects a processing position before the slit width calculation from the processing positions of the plurality of modified regions 12 (SD1, SD2, SD3) (step S2). Then, the control unit 8 calculates the slit width at the selected processing position (step S3). Specifically, the control unit 8 calculates the slit width at the selected processing position by, for example, the procedures 1 to 4 described above.

Subsequently, the control unit 8 determines whether or not the derived slit width is appropriate (step S4). Specifically, the control unit 8 determines whether or not the derived slit width is smaller than the limit slit width (limit slit value). In addition, the control unit 8 may determine whether or not the derived slit width is a slit width that increases the length of a crack extending from the modified region 12.

If it is determined in step S4 that the slit width is not appropriate, the control unit 8 controls the display 150 to display an alarm (step S5).

Displaying an alarm means, for example, displaying information indicating that processing is not possible when the slit width is the limit slit width. In addition, displaying an alarm means, for example, displaying information for prompting a change in processing conditions when the slit width is a slit width that increases the length of a crack.

If it is determined in step S4 that the slit width is appropriate, the control unit 8 determines the derived slit width as a slit width at the selected processing position (step S6). Subsequently, the control unit 8 determines whether or not there is an unselected processing position (step S7). If there is an unselected processing position, the process is performed again from the processing of step S2. On the other hand, if there is no unselected processing position (if the slit width is determined for all processing positions), the control unit 8 sets a slit pattern corresponding to the derived slit width in the spatial light modulator 32 for each processing position, and starts the processing (step S8). The above is the beam width adjustment process.

Next, the function and effect of the laser processing device 1 according to the present embodiment will be described.

The laser processing device 1 according to the present embodiment includes: the stage 2 that supports the wafer 20 having the front surface 21a, on which a plurality of functional elements 22a are formed and the street region 23 extends so as to pass between the adjacent functional elements 22a, and the back surface 21b on a side opposite to the front surface 21a; the light source 31 that emits laser light to the wafer 20 from the front surface 21a side to form one or more modified regions 12 inside the wafer 20; the spatial light modulator 32 as a beam width adjusting unit that adjusts the beam width of the laser light; and the control unit 8 that controls the spatial light modulator 32 so that the beam width of the laser light is adjusted to be equal to or less than the width of the street region 23 and a target beam width according to surface information including the position and height of the structure 22x forming the functional element 22a adjacent to the street region 23.

In the laser processing device 1, in a configuration in which the laser light is emitted to the wafer 20 from the front surface 21a side on which a plurality of functional elements 22a are formed, the beam width of the laser light is adjusted to be equal to or less than the width of the street region 23 on the front surface 21a and the target beam width according to the position and height of the structure 22x forming the functional element 22a. In this manner, since the beam width of the laser light is adjusted to be equal to or less than the width of the street region 23 and the target beam width considering the position and height of the structure 22x forming the functional element 22a, it is possible to adjust the beam width of the laser light so that not only is the laser light confined within the width of the street region 23, but also the laser light is not blocked by the structure 22x. Therefore, it is possible to perform desired laser emission (emission of laser that is confined within the width of the street region 23 and is not blocked by the structure 22x) by suppressing the blocking of the laser light by the structure 22x such as a circuit.

That is, according to the laser processing device 1 according to the present embodiment, it is possible to suppress a reduction in the output of the laser light inside the wafer 20 due to the blocking of the laser light by the structure 22x. In addition, when the laser light is emitted to the structure 22x such as a circuit, it is conceivable that an undesirable beam enters the inside of the wafer 20 due to interference to degrade the processing quality. In this respect, by suppressing the blocking of the laser light by the structure 22x (emission of the laser light to the structure 22x) as described above, it is possible to prevent such degradation of the processing quality. In addition, depending on the structure 22x, it is conceivable that the structure is melted by the emission of the laser light. In this respect as well, by suppressing the blocking of the laser light by the structure 22x (emission of the laser light to the structure 22x) as described above, it is possible to avoid the influence of the laser light on the structure 22x (for example, melting of the structure 22x).

The spatial light modulator 32 may function as a slit portion for adjusting the beam width by blocking a part of the laser light, and the control unit 8 may derive a slit width relevant to a transmission region of the laser light in the slit portion based on the surface information and set the slit width in the slit portion. According to such a configuration, it is possible to adjust the beam width easily and reliably.

When the derived slit width is smaller than a limit value that enables formation of the modified region, the control unit 8 may output information indicating that processing is not possible to the outside. Therefore, since a situation is avoided in which processing is performed despite being in a non-processable state in which a modified region cannot be formed (useless processing is performed), it is possible to perform efficient processing.

When the derived slit width is a slit width that increases a length of a crack extending from the modified region, the control unit 8 may output information for prompting a change in processing conditions to the outside. Therefore, since it is possible to prompt a change in the processing conditions when the appropriate processing cannot be performed, it is possible to perform smooth processing.

The control unit 8 may derive the slit width by further considering a processing depth of the laser light in the wafer 20. Even if the surface information is the same, the appropriate slit width differs depending on the processing depth. In this respect, by deriving the slit width in consideration of the processing depth, it is possible to derive a more appropriate slit width. Therefore, it is possible to appropriately suppress the blocking of the laser light by the structure 22x.

When a plurality of modified regions 12 are formed at different depths inside the wafer 20 by emitting the laser light to the inside of the wafer 20, the control unit 8 may derive the slit width for each combination of the surface information and the processing depth of the laser light. Thus, since the slit width is derived for each combination of different processing depths and surface information, a more appropriate slit width is derived. Therefore, it is possible to appropriately suppress the blocking of the laser light by the structure 22x.

The control unit 8 may control the spatial light modulator 32 by further considering the amount of laser incidence position shift on the front surface 21a during processing. It is considered that the processing line is gradually shifted as the processing progresses. In this regard, by specifying such a shift amount in advance and controlling the spatial light modulator 32 (setting the slit pattern) in consideration of the shift amount, it is possible to suppress the blocking of the laser light by the structure 22x even when the processing line is shifted.

Although the embodiments of the present invention have been described, the present invention is not limited to the above embodiments. For example, although it has been described that the control unit 8 adjusts the beam width of the laser light by setting the slit pattern in the spatial light modulator 32, the method of adjusting the beam width is not limited to this. For example, the beam width may be adjusted by setting a physical slit instead of the slit pattern. In addition, for example, the beam width may be adjusted by adjusting the ellipticity of the laser light in the spatial light modulator 32.

### REFERENCE SIGNS LIST

1: laser processing device, 2: stage, 8: control unit, 20: wafer, 21a: front surface (first surface), 21b: back surface (second surface), 22a: functional element (element), 22x: structure, 23: street region (street), 31: light source (emission unit), 32: spatial light modulator (beam width adjusting unit).

1. A laser processing device, comprising:
a stage that supports a wafer having a first surface, on which a plurality of elements are formed and a street extends so as to pass between adjacent elements, and a second surface on a side opposite to the first surface;
an emission unit configured to emit laser light to the wafer from the first surface side to form one or more modified regions inside the wafer;
a beam width adjusting unit configured to adjust a beam width of the laser light; and
a control unit configured to control the beam width adjusting unit so that the beam width of the laser light is adjusted to be equal to or less than a width of the street and a target beam width according to surface information including a position and a height of a structure forming an element adjacent to the street.

2. The laser processing device according to claim 1,
wherein the beam width adjusting unit has a slit portion for adjusting the beam width by blocking a part of the laser light, and
the control unit derives a slit width relevant to a transmission region of the laser light in the slit portion based on the surface information, and sets the slit width in the slit portion.

3. The laser processing device according to claim 2,
wherein, when the derived slit width is smaller than a limit value that enables formation of the modified region, the control unit outputs information indicating that processing is not possible to an outside.

4. The laser processing device according to claim 2,
wherein, when the derived slit width is a slit width that increases a length of a crack extending from the modified region, the control unit outputs information for prompting a change in processing conditions to an outside.

5. The laser processing device according to claim 2,
wherein the control unit derives the slit width by further considering a processing depth of the laser light in the wafer.

6. The laser processing device according to claim 5,
wherein, when a plurality of modified regions are formed at different depths inside the wafer by emitting the laser light to an inside of the wafer, the control unit derives the slit width for each combination of the surface information and the processing depth of the laser light.

7. The laser processing device according to claim 1,
wherein the control unit controls the beam width adjusting unit by further considering an amount of laser incidence position shift on the first surface during processing.

8. An inspection method, comprising:
setting a wafer having a first surface, on which a plurality of elements are formed and a street extends so as to pass between adjacent elements, and a second surface on a side opposite to the first surface;
receiving an input of a width of the street and surface information including a position and a height of a structure forming an element adjacent to the street;
controlling a beam width adjusting unit that adjusts a beam width of laser light to be equal to or less than a target beam width according to the surface information; and
controlling an emission unit that emits laser light so that the laser light is emitted to the wafer from the first surface side.
